(19) United States
(12) Patent Application Publication
(10) Pub. No.: US 2007/0181530 A1
(43) Pub. Date: Aug. 9, 2007

(54) Reducing line edge roughness

(75) Inventors: Zhi-Song Huang, Fremont, CA (US); S.M. Reza Sadjadi, Saratoga, CA (US); Lumin Li, Santa Clara, CA (US); Conan Chiang, Los Altos, CA (US)

Correspondence Address: BEYER WEAVER LLP, P.O. BOX 70250, OAKLAND, CA, 94612-0250, US

(73) Assignee: Lam Research Corporation

(21) Appl. No.: 11/350,488

(22) Filed: Feb. 8, 2006

(51) Int. Cl. C23F 1/00; H01L 21/461; H01L 21/302

(52) U.S. Cl. 216/67; 438/710

(57) ABSTRACT

A method of forming features in an etch layer disposed below a mask with features is provided. The mask is conditioned. The conditioning, comprising providing a conditioning gas consisting essentially of at least one noble gas, forming a plasma from the conditioning gas, and exposing the mask to the plasma from the conditioning gas. The features of the mask are shrunk. Features are etched into the etch layer through the shrunk features of the mask.

### BACKGROUND OF THE INVENTION

The present invention relates to the formation of semiconductor devices. More particularly, the invention relates to the etching of features into a dielectric layer.

During semiconductor wafer processing, features of the semiconductor device are defined in the wafer using well-known patterning and etching processes. In these processes, a photoresist (PR) material is deposited on the wafer and then is exposed to light filtered by a reticle. The reticle is generally a glass plate that is patterned with exemplary feature geometries that block light from propagating through the reticle.

After passing through the reticle, the light contacts the surface of the photoresist material. The light changes the chemical composition of the photoresist material such that a developer can remove a portion of the photoresist material. In the case of positive photoresist materials, the exposed regions are removed, and in the case of negative photoresist materials, the unexposed regions are removed. Thereafter, the wafer is etched to remove the underlying material from the areas that are no longer protected by the photoresist material, and thereby define the desired features in the wafer.

One problem in such processes is that line edge roughness of the mask features may be transferred to the etch features.

### SUMMARY OF THE INVENTION

To achieve the foregoing and in accordance with the purpose of the present invention, a method of forming features in an etch layer disposed below a mask with features is provided. The mask is conditioned. The conditioning, comprises providing a conditioning gas consisting essentially of at least one noble gas, forming a plasma from the conditioning gas, and exposing the mask to the plasma from the conditioning gas. The features of the mask are shrunk. Features are etched into the etch layer through the shrunk features of the mask.

In another manifestation of the invention, an apparatus for forming features in an etch layer is provided, where the etch layer is supported by a substrate and wherein the etch layer is covered by an etch mask with mask features with a first CD. A plasma processing chamber is provided. The plasma processing chamber comprises a chamber wall forming a plasma processing chamber enclosure, a substrate support for supporting a substrate within the plasma processing chamber enclosure, a pressure regulator for regulating the pressure in the plasma processing chamber enclosure, at least one electrode for providing power to the plasma processing chamber enclosure for sustaining a plasma, a gas inlet for providing gas into the plasma processing chamber enclosure, and a gas outlet for exhausting gas from the plasma processing chamber enclosure. A gas source is in fluid connection with the gas inlet and comprises a noble gas source, a deposition gas source, a profile shaping phase gas source, and an etching gas source. A controller is controllably connected to the gas source and the at least one electrode and comprises at least one processor, and computer readable media. The computer readable media comprises computer readable code for conditioning the etch mask, comprising computer readable code for providing a flow of only noble gas from the noble gas source, computer readable code for energizing the at least one electrode to create a plasma from the noble gas, and computer readable code for stopping the flow of the noble gas to the plasma processing chamber enclosure, computer readable code for shrinking features of the etch mask, comprising computer readable code for depositing a deposition layer on the mask and computer readable code for shaping a profile of the deposited layer, and computer readable code for etching features into the etch layer through the mask.

These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a high level flow chart of a process that may be used in an embodiment of the invention.

FIGS. 2A-D are schematic cross-sectional views of a stack processed according to an embodiment of the invention.

FIGS. 3A-C are top views of the stack shown in FIGS. 2A-D.

FIG. 4 is a schematic view of a plasma processing chamber that may be used in practicing the invention.

FIGS. 5A-B illustrate a computer system, which is suitable for implementing a controller used in embodiments of the present invention.

FIG. 6 is a more detailed flow chart of a conditioning process.

FIG. 7 is a more detailed flow chart of the shrink mask features process.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

Some causes of line edge roughening are lack of mobility of the photoresist or mask, stress mismatch between the photoresist, mask, and etch by products (polymers), and photoresist or mask chemical modifications.

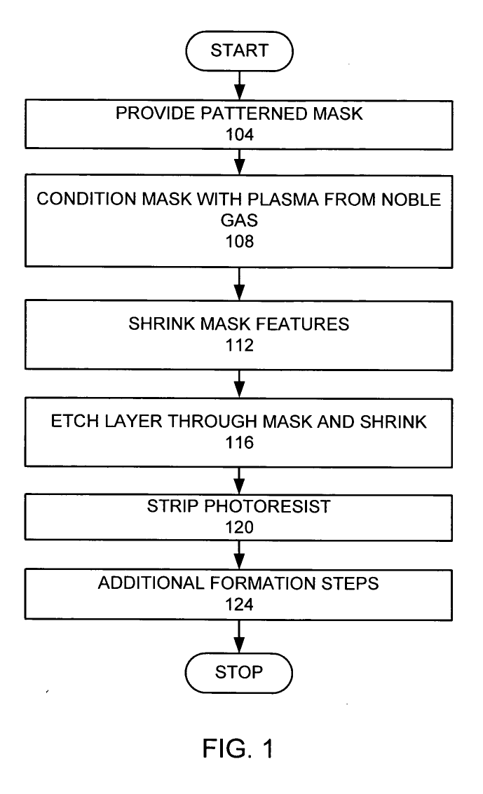

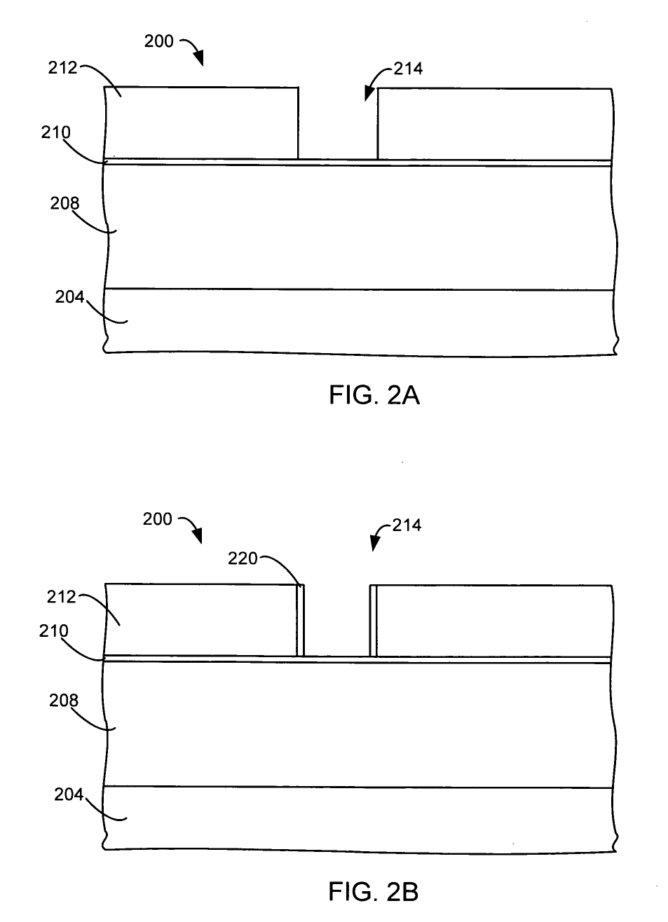

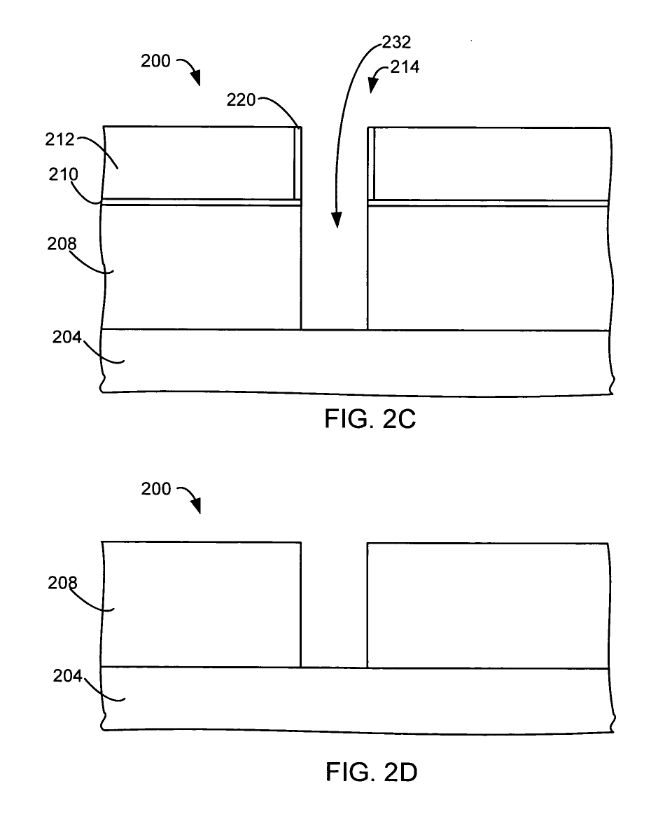

To facilitate understanding, FIG. 1 is a high level flow chart of a process that may be used in an embodiment of the invention. A patterned photoresist mask is provided (step 104). FIG. 2A is a schematic cross-sectional view of an etch layer 208 over a substrate 204, with a patterned mask 212 with a mask feature 214, over an ARC 210, over the etch layer 208 forming a stack 200. The mask 212 has a mask feature critical dimension (CD), which may be the widest part of the width of the smallest possible feature. To provide the patterned mask, a photoresist layer may be first formed over the etch layer. Presently, for 248 nm photoresist a typical CD for the photoresist may be 230-250 nm, using conventional processes.

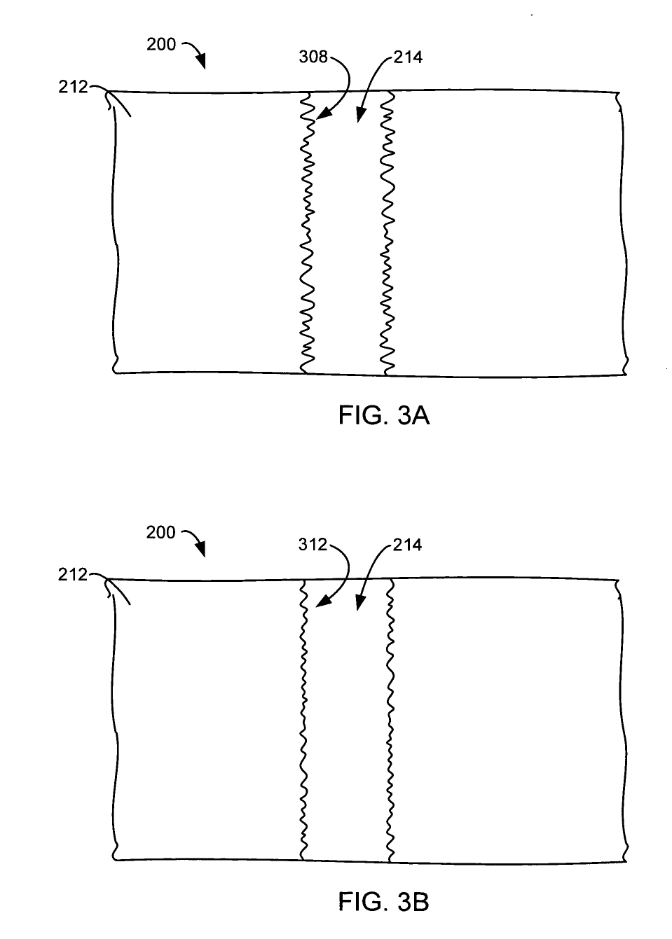

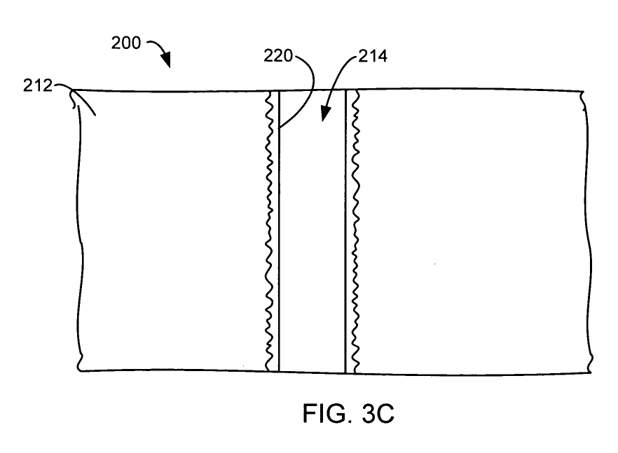

FIG. 3A is a top view of the stack 200 in FIG. 2A. In this example, the mask feature 214 is a trench mask feature. Instead of the line edge of the mask feature being smooth, the line edge 308 is rough, as shown. The roughness is exaggerated and is not to scale for illustrative purposes.

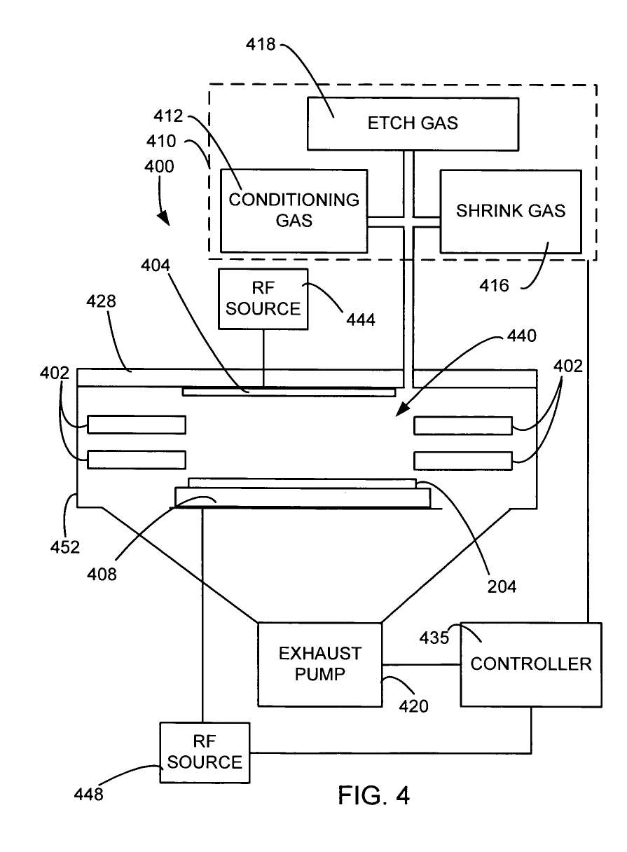

The mask is conditioned using a plasma from a noble gas (step 108). The substrate 204 is placed in a processing chamber. FIG. 4 is a schematic view of a processing chamber 400 that may be used for conditioning the mask. The plasma processing chamber 400 comprises confinement rings 402, an upper electrode 404, a lower electrode 408, a gas source 410, and an exhaust pump 420. The gas source 410 comprises a conditioning gas source 412. The gas source 410 may comprise additional gas sources, such as a shrink gas source 416 and an etching gas source 418 to allow a shrink process and etch process to be done in situ, in the same chamber. Within plasma processing chamber 400, the substrate 204 is positioned upon the lower electrode 408. The lower electrode 408 incorporates a suitable substrate chucking mechanism (e.g., electrostatic, mechanical clamping, or the like) for holding the substrate 204. The reactor top 428 incorporates the upper electrode 404 disposed immediately opposite the lower electrode 408. The upper electrode 404, lower electrode 408, and confinement rings 402 define the confined plasma volume 440. Gas is supplied to the confined plasma volume by the gas source 410 and is exhausted from the confined plasma volume through the confinement rings 402 and an exhaust port by the exhaust pump 420. A first RF source 444 is electrically connected to the upper electrode 404. A second RF source 448 is electrically connected to the lower electrode 408. Chamber walls 452 surround the confinement rings 402, the upper electrode 404, and the lower electrode 408. Both the first RF source 444 and the second RF source 448 may comprise a 27 MHz power source and a 2 MHz power source. Different combinations of connecting RF power to the electrode are possible. In the case of Lam Research Corporation's Dual Frequency Capacitive (DFC) System, made by LAM Research Corporation™ of Fremont, Calif., which may be used in a preferred embodiment of the invention, both the 27 MHz and 2 MHz power sources make up the second RF power source 448 connected to the lower electrode, and the upper electrode is grounded. A controller 435 is controllably connected to the RF sources 444, 448, exhaust pump 420, and the gas source 410. The DFC System would be used when the etch layer 208 is a dielectric layer, such as silicon oxide or organo silicate glass.

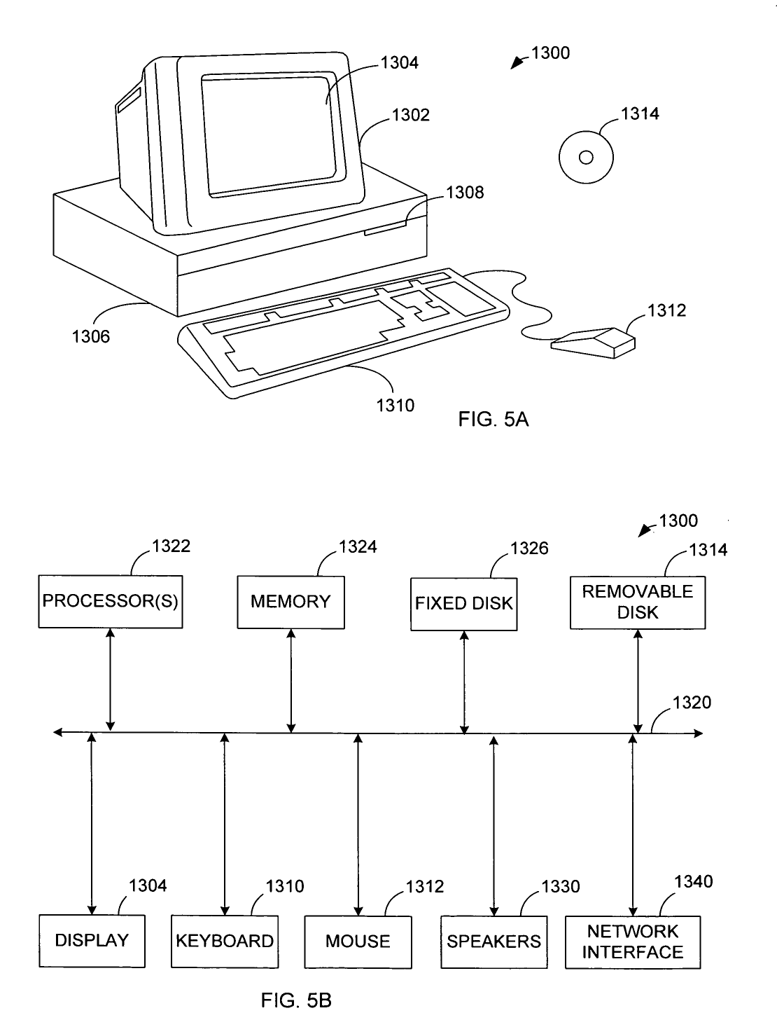

FIGS. 5A and 5B illustrate a computer system 1300, which is suitable for implementing a controller 435 used in embodiments of the present invention. FIG. 5A shows one possible physical form of the computer system. Of course, the computer system may have many physical forms ranging from an integrated circuit, a printed circuit board, and a small handheld device up to a huge super computer. Computer system 1300 includes a monitor 1302, a display 1304, a housing 1306, a disk drive 1308, a keyboard 1310, and a mouse 1312. Disk 1314 is a computer-readable medium used to transfer data to and from computer system 1300.

FIG. 5B is an example of a block diagram for computer system 1300. Attached to system bus 1320 is a wide variety of subsystems. Processor(s) 1322 (also referred to as central processing units, or CPUs) are coupled to storage devices, including memory 1324. Memory 1324 includes random access memory (RAM) and read-only memory (ROM). As is well known in the art, ROM acts to transfer data and instructions uni-directionally to the CPU and RAM is used typically to transfer data and instructions in a bi-directional manner. Both of these types of memories may include any suitable of the computer-readable media described below. A fixed disk 1326 is also coupled bi-directionally to CPU 1322; it provides additional data storage capacity and may also include any of the computer-readable media described below. Fixed disk 1326 may be used to store programs, data, and the like and is typically a secondary storage medium (such as a hard disk) that is slower than primary storage. It will be appreciated that the information retained within fixed disk 1326 may, in appropriate cases, be incorporated in standard fashion as virtual memory in memory 1324. Removable disk 1314 may take the form of any of the computer-readable media described below.

CPU 1322 is also coupled to a variety of input/output devices, such as display 1304, keyboard 1310, mouse 1312, and speakers 1330. In general, an input/output device may be any of: video displays, track balls, mice, keyboards, microphones, touch-sensitive displays, transducer card readers, magnetic or paper tape readers, tablets, styluses, voice or handwriting recognizers, biometrics readers, or other computers. CPU 1322 optionally may be coupled to another computer or telecommunications network using network interface 1340. With such a network interface, it is contemplated that the CPU might receive information from the network, or might output information to the network in the course of performing the above-described method steps. Furthermore, method embodiments of the present invention may execute solely upon CPU 1322 or may execute over a network such as the Internet in conjunction with a remote CPU that shares a portion of the processing.

In addition, embodiments of the present invention further relate to computer storage products with a computer-readable medium that have computer code thereon for performing various computer-implemented operations. The media and computer code may be those specially designed and constructed for the purposes of the present invention, or they may be of the kind well known and available to those having skill in the computer software arts. Examples of computer-readable media include, but are not limited to: magnetic media such as hard disks, floppy disks, and magnetic tape; optical media such as CD-ROMs and holographic devices; magneto-optical media such as floptical disks; and hardware devices that are specially configured to store and execute program code, such as application-specific integrated circuits (ASICs), programmable logic devices (PLDs) and ROM and RAM devices. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

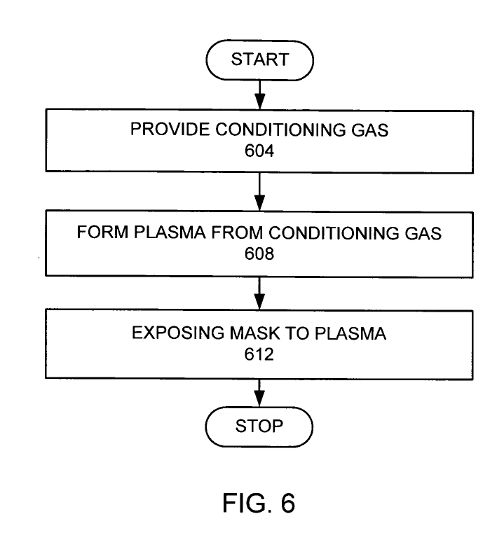

FIG. 6 is a more detailed flow chart of the step of conditioning the mask with plasma from a noble gas. A conditioning gas is provided (step 604). In the preferred embodiment of the invention, the conditioning gas consists essentially of one or more noble gases, such as Ar, Xe, Ne, He, and Kr and any combination thereof. A plasma is formed from the conditioning gas (step 608) so that the plasma consists essentially of a noble gas formed into a plasma. The mask is exposed to the plasma from the conditioning gas (step 612).

FIG. 3B is a top view of the stack 200 after the conditioning has been performed. Without being bound by theory, it is believed that after conditioning, the line edge roughness 312 of the mask feature 214 is reduced by selectively removing some of the peaks in the line edge roughness, as shown.

Preferably, the conditioning process does not significantly etch the mask or the etch layer.

A shrink mask features procedure is performed (step 112). FIG. 2B is a schematic cross-sectional view of the patterned photoresist mask 212 with a sidewall layer 220 formed over the sidewalls of the feature 214 after the shrink process. The sidewall layer preferably forms substantially vertical and conformal sidewalls. An example of a substantially vertical sidewall is a sidewall that from bottom to top makes an angle of between 88° to 90° with the bottom of the feature. Conformal sidewalls have a deposition layer that has substantially the same thickness from the top to the bottom of the feature. Non-conformal sidewalls may form a faceting or a bread-loafing formation, which provide non-substantially vertical sidewalls. Tapered sidewalls (from the faceting formation) or bread-loafing sidewalls may increase the deposited layer CD and provide a poor etching mask. Preferably, the shrink reduces the CD of the mask features by more than 10%. More preferably, the shrink reduces the CD of the mask features by between 30% to 80%. FIG. 3C is a top view of the stack 200 after the shrink process. By experiment, it has been found that providing a conditioning step before the shrink significantly reduces line edge roughness compared to a shrink without the conditioning step.

Features are then etched into the etch layer 208 through the formed sidewall layer 220 forming the shrunk mask features (step 116). FIG. 2C shows a feature 232 etched into the etch layer 208.

The photoresist and sidewall layer may then be stripped (step 120). This may be done as a single step or two separate steps with a separate deposited layer removal step and photoresist strip step. Ashing may be used for the stripping process. FIG. 2D shows the stack 200 after the deposited layer and photoresist mask have been removed. Additional formation steps may be performed (step 124). For example, the trench feature may be filled with a conductive material.

### EXAMPLE

In one example, a patterned mask is placed over a substrate 204, with an etch layer 208, and an ARC layer 210 (step 104). In this example, the substrate is a silicon wafer. The etch layer 208 is organosilicate glass. The patterned mask 212 is a photoresist mask. In other embodiments, the patterned mask may be other polymer type masks, such as amorphous carbon. The substrate is placed in a process chamber, such as described above.

The mask is conditioned (step 108). In this example, a conditioning gas consisting essentially of Ar is provided (step 604). A plasma is formed from the Ar gas (step 608). The pressure is set at 240 mTorr. A power of 200 Watts is provided. The mask 212 is exposed to the plasma (step 612) for typically 30 seconds. The conditioning process is then stopped.

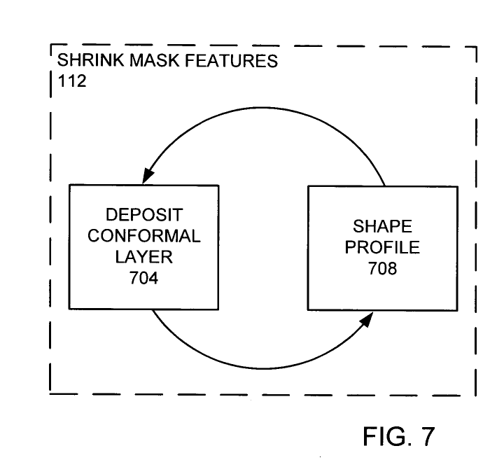

After the conditioning is complete, a shrink process is provided to shrink the mask features (step 112). FIG. 7 is a more detailed flow chart of the shrink process. This process is a cyclical process that is repeated at least twice. A conformal layer is deposited over the photoresist layer (step 704). The conformal layer is then subjected to a profile shaping step, such as etching back to remove any deposition at the bottom of the photoresist features to form sidewall layers (step 708). Preferably, this process is repeated between 3 and 50 cycles. More preferably, this process is repeated between 4 and 10 cycles.

In this example, the deposit conformal layer phase (step 704) comprises providing a deposition gas and generating a plasma from the deposition gas to form a deposition layer. In this example, the deposition gas comprises a polymer forming recipe. An example of such a polymer forming recipe is a hydrocarbon gas, such as CH₄ and C₂H₄, and a fluorocarbon gas, such as CH₃F, CH₂F₂, CHF₃, C₄F₆, and C₄F₈. Another example of a polymer forming recipe would be a fluorocarbon chemistry and a hydrogen containing gas, such as a recipe of CF₄ and H₂. In a preferred embodiment, CF₄ and H₂ have a molar ratio (CF₄:H₂) in the range of 1:2 to 2:1. In this example, power is supplied at 400 Watts at 2 MHz and 800 Watts at 27 MHz.

In this example, the shape profile phase (step 708) comprises providing a profile shaping phase gas and generating a profile shaping phase plasma from the profile shaping phase gas to shape the profile of the deposition layer. The profile shaping phase gas is different from the deposition gas. The deposition phase (step 704) and the profile shaping phase (step 708) occur at different times sequentially in a cyclical process. In this example, the profile shaping gas comprises a fluorocarbon chemistry, such as CF₄, CHF₃, and CH₂F₂. Other additives such as O₂, N₂, and H₂ may be added. In this example, power is supplied at 0 Watts at 2 MHz and 800 Watts at 27 MHz.

In other embodiments, a shrink cycle may further include additional deposition and/or profile shaping steps.

After the shrink is complete, the etch layer is etched (step 116). A typical process for etching a dielectric material or a conductor material (Si, Al, W, WSI, etc) can be used.

To strip the photoresist and the mask shrink (step 120) an oxygen ashing may be used.

Providing the inert gas plasma conditioning before the shrink has been unexpectedly found to beneficially reduce line edge roughness of the resulting feature.

In a preferred embodiment of the invention, the mask conditioning, the mask feature shrink, and etching of the etch layer may be done in situ in the same etch chamber, as shown.

While in this example the mask is a photoresist mask, in other embodiments, the mask may be of other polymer-type masks such as amorphous carbon, amorphous Si, SiO2 or SiN, SiC, TiN, etc.

While this invention has been described in terms of several preferred embodiments, there are alterations, modifications, permutations, and various substitute equivalents, which fall within the scope of this invention. It should also be noted that there are many alternative ways of implementing the methods and apparatuses of the present invention. It is therefore intended that the following appended claims be interpreted as including all such alterations, modifications, permutations, and various substitute equivalents as fall within the true spirit and scope of the present invention.

What is claimed is:

1. A method of forming features in an etch layer disposed below a mask with features, comprising:
conditioning the mask, comprising:
providing a conditioning gas consisting essentially of at least one noble gas;
forming a plasma from the conditioning gas; and
exposing the mask to the plasma from the conditioning gas;
shrinking the features of the mask; and
etching features into the etch layer through the shrunk features of the mask.

2. The method, as recited in claim 1, wherein the shrinking the features of the mask comprises a plurality of cycles, wherein each cycle comprises:
depositing a layer on the mask; and
shaping a profile of the deposited layer.

3. The method, as recited in claim 2, wherein the conditioning gas consists essentially of one of Ar, He, Xe, Kr, and Ne and any combination thereof.

4. The method, as recited in claim 3, further comprising stripping the mask.

5. The method, as recited in claim 4, wherein the mask is a polymer type mask.

6. The method, as recited in claim 5, wherein the shrinking of the features is preformed for 3 to 50 cycles.

7. The method, as recited in claim 6, wherein the conditioning the mask, the shrinking the features of the mask, and etching the etch layer are done in situ in the same chamber.

8. The method, as recited in claim 7, wherein the conditioning the mask reduces line edge roughness of the features etched into the etch layer.

9. The method, as recited in claim 8, wherein the shrinking the features of the mask forms substantially vertical sidewalls.

10. The method, as recited in claim 9, wherein the mask features have a critical dimension, wherein the shrinking the features of the mask reduces the critical dimension of the mask features by at least 10%.

11. The method, as recited in claim 2, wherein the shrinking of the features is preformed for 3 to 50 cycles.

12. The method, as recited in claim 1, wherein the mask is a polymer type mask.

13. The method, as recited in claim 1, wherein the conditioning gas consists essentially of only one of Ar, He, and Xe, Kr, Ne.

14. The method, as recited in claim 1, wherein the conditioning the mask, the shrinking the features of the mask, and etching the etch layer are done in situ in the same chamber.

15. The method, as recited in claim 1, wherein the conditioning the mask reduces line edge roughness of the features etched into the etch layer.

16. The method, as recited in claim 1, wherein the shrinking the features of the mask forms substantially vertical sidewalls.

17. The method, as recited in claim 1, wherein the mask features have a critical dimension, wherein the shrinking the features of the mask reduces the critical dimension of the mask features by at least 10%.

18. An apparatus for forming features in an etch layer, wherein the etch layer is supported by a substrate and wherein the etch layer is covered by an etch mask with mask features with a first CD, comprising:
a plasma processing chamber, comprising:
a chamber wall forming a plasma processing chamber enclosure;
a substrate support for supporting a substrate within the plasma processing chamber enclosure;
a pressure regulator for regulating the pressure in the plasma processing chamber enclosure;
at least one electrode for providing power to the plasma processing chamber enclosure for sustaining a plasma;
a gas inlet for providing gas into the plasma processing chamber enclosure; and
a gas outlet for exhausting gas from the plasma processing chamber enclosure;
a gas source in fluid connection with the gas inlet, comprising:
a noble gas source;
a deposition gas source;
a profile shaping phase gas source; and
an etching gas source; and
a controller controllably connected to the gas source and the at least one electrode, comprising:
at least one processor; and
computer readable media, comprising:
computer readable code for conditioning the etch mask, comprising:
computer readable code for providing a flow of only noble gas from the noble gas source; and
computer readable code for energizing the at least one electrode to create a plasma from the noble gas;
computer readable code for stopping the flow of the noble gas to the plasma processing chamber enclosure;
computer readable code for shrinking features of the etch mask, comprising
computer readable code for depositing a deposition layer on the mask; and
computer readable code for shaping a profile of the deposited layer; and
computer readable code for etching features into the etch layer through the mask.

19. The apparatus, as recited in claim 18, wherein the computer readable code for depositing a deposition layer on the mask comprises:
computer readable code for providing a deposition gas from the deposition gas source;
computer readable code for energizing the at least one electrode to create a plasma from the deposition gas; and
computer readable code for stopping the deposition gas from the deposition gas, and
wherein the computer readable code for shaping the profile of the deposited layer, comprises:
computer readable code for providing a profile shaping phase gas from the profile shaping phase gas source;
computer readable code for energizing the at least one electrode to create a plasma from the profile shaping phase gas; and
computer readable code for stopping the profile shaping phase gas from the profile shaping phase gas source.

20. The apparatus, as recited in claim 19, wherein the computer readable code for etching features into the etch layer through the mask comprises:
computer readable code for providing an etching gas from the etching gas source;
computer readable code for energizing the at least one electrode to create a plasma from the etching gas.
